(19) United States
(12) Patent Application Publication
(10) Pub. No.: US 2010/0040659 A1
(43) Pub. Date: Feb. 18, 2010

(54) ANTIMICROBIAL MATERIAL, AND A METHOD FOR THE PRODUCTION OF AN ANTIMICROBIAL MATERIAL

(75) Inventors: Matthias Fahland, Dresden (DE); Nicolas Schiller, Helmsdorf (DE); Tobias Vogt, Kurort Johnsdorf (DE); John Fahlteich, Dresden (DE)

Correspondence Address: GREENBLUM & BERNSTEIN, P.L.C., 1950 ROLAND CLARKE PLACE, RESTON, VA, 20191, US

(73) Assignee: FRAUNHOFER-GESELLSCHAFT ZUR FOERDERUNG DER ANGEWAD FORSCHUNG E.V., Muenchen (DE)

(21) Appl. No.: 12/519,900

(22) PCT Filed: Nov. 30, 2007
(86) PCT No.: PCT/EP2007/010412

§ 371 Date: Jun. 18, 2009

(30) Foreign Application Priority Data
Dec. 19, 2006 (DE) 10 2006 060 057.6

(51) Int. Cl. A01N 25/08; A01N 59/16; A01N 59/20; A01P 1/00; C23C 14/34; C23C 14/35

(52) U.S. Cl. 424/409; 424/618; 424/630; 424/641; 204/192.15

(57) ABSTRACT

The invention relates to an antimicrobial material and a method for producing an antimicrobial material, which is deposited on a substrate (2), comprising the steps: Providing the substrate (2) in a vacuum working chamber (3); atomizing a biocidal metal by means of a sputtering device inside the vacuum working chamber (3) in the presence of an inert gas; simultaneous introduction of a precursor, which contains silicon, carbon, hydrogen and oxygen, into the vacuum working chamber (3) so that the sputtered metal particles and the precursor are exposed to a plasma action; deposition of a material on the substrate (2) such that a matrix is formed through the plasma activation of the precursor, in which matrix clusters of sputtered metal particles are incorporated.

### CROSS-REFERENCE TO RELATED APPLICATIONS

This application is a U.S. National Stage of International Application No. PCT/EP2007/010412 filed Nov. 30, 2007, which claims priority of German Patent Application No. 10 2006 060 057.6 filed Dec. 19, 2006. Further, the disclosure of International Application No. PCT/EP2007/010412 is expressly incorporated by reference herein in its entirety.

### BACKGROUND OF THE INVENTION

1. Field of the Invention

The invention relates to an antimicrobial material and a method for producing an antimicrobial material, which can be used, for example, for cleaning and disinfecting purposes.

2. Discussion of Background Information

A number of cleaners and disinfectants are known from the prior art, which can be present in very diverse forms. In particular there is a broad range of fabrics and nonwoven fabrics that are covered with antimicrobial materials. Their operative mechanism can thereby be very diverse. Chemical effects of specific molecules are often utilized hereby. However, these have the disadvantage that the antimicrobial molecules often cannot be mobilized quickly enough. Furthermore, it is a disadvantage that these molecules can cause undesirable side effects in the environment and in people, appropriate handling and disposal measures being necessary.

For this reason inorganic disinfectants are very often favored, in particular substances that can release metal ions, in particular silver ions (U.S. Pat. No. 6,821,936 B2). Antimicrobial properties of metals, for example for silver, copper or zinc for disinfecting and for use in cleaning and medical technology are likewise known.

A distinction is thereby made between essentially two effects. In most cases the biocidal effect of the metal is desirable. This means killing microorganisms. In contrast thereto is the cytotoxic effect, that is, the destruction of biological tissue, which often represents an undesirable effect.

With metals, in particular the presence of silver in the form of particles with typical dimensions between 5 nm and 100 nm is advantageous for the desired release of metal ions (DE 101 46 050 A1).

The important factor for an effective application of silver is the manner of application. In EP 1 644 010 A2 a liquid with antimicrobial effect is described, which contains silver-containing particles. In DE 10 2005 020 889 A1 a woven fabric is disclosed which has been treated with silver-containing substances.

It is known that a problem often lies in releasing the correct amount of silver at a corresponding application time. With some applications the object lies in achieving a stable biocidal effect over a long time period, wherein a cytotoxic effect should not be caused at any time, in particular after the start of an application. A solution to this problem is given in WO 2005/049699 A2. There a carrier material, for example, a nonwoven fabric or an implant, is described, which is first coated with silver in the form of particles of a suitable size. Subsequently, this silver layer is covered by a transport control layer, which regulates the release of the silver to the environment for a longer period. In particular the release of cytotoxic concentrations is avoided through a transport control layer of this type, through which the silver ions must first diffuse. This source also describes different methods for applying these two layers to the carrier material. Among other things a vacuum method is disclosed in which the silver is evaporation-coated or sputtered. Subsequently a silicon-containing transport control layer is applied over the silver layer by plasma polymerization.

One disadvantage of the method described in WO 2005/049699 A2 lies in that the transport control layer must be deposited with a high precision in order to adjust the desired properties precisely. Although the described vacuum methods are able to achieve this precision, the use of woven fabrics as carrier medium requires a separate adjustment of the two layers for each specific woven fabric. This situation is due to the microscopic structure of woven fabrics. During the coating process the coating material penetrates into the woven fabric and is deposited in this manner not only on the outer fibers, but also on fibers in the interior of the woven fabric. The knowledge of the effective layer thickness and the effective coating rate is important for a successful control with a coating process of this type. This means the layer thickness, or the coating rate, which would occur with the same conditions on a smooth substrate. Due to the internal structure of a woven fabric, however, the true layer thicknesses of silver layer and transport control layer on the fibers, which ultimately decide the biocidal effect, are different with respect to the effective layer thicknesses with smooth substrates. Furthermore, the layer thicknesses on the outer fibers have different values from the layer thicknesses on fibers lying deeper. At the same time limits are thus indicated for an optimal design of a multilayered system described in WO 2005/049699.

### SUMMARY OF THE INVENTION

The invention is directed to creating an antimicrobial material and a method for the production thereof, with which the referenced disadvantages of the prior art are overcome. In particular, the method should make it possible to produce a material, which, deposited on different carrier materials, largely causes the same biocidal effects.

According to the of the invention, a method for producing an antimicrobial material, which is deposited on a substrate, includes a) providing the substrate in a vacuum working chamber, b) atomizing a biocidal metal by means of a sputtering device inside the vacuum working chamber in the presence of an inert gas, c) simultaneous introduction of a precursor, which contains silicon, carbon, hydrogen and oxygen, into the vacuum working chamber so that the sputtered metal particles and the precursor are exposed to a plasma action, and d) deposition of a material on the substrate such that a matrix is formed through the plasma activation of the precursor, in which matrix clusters of sputtered metal particles are incorporated. Moreover, in accordance with the invention, an antimicrobial material is produced according to the above-noted method and contains carbon, hydrogen, silicon and oxygen, and the antimicrobial material furthermore contains clusters of particles of a biocidal metal with a size of 3 nm to 40 nm. Further advantageous embodiments of the invention are shown by the dependent claims.

According to the invention, an antimicrobial material is deposited on a substrate. The substrate to be coated is arranged in a vacuum chamber in which a biocidal metal is atomized by a sputtering device in the presence of an inert gas and under the influence of plasma. Copper or zinc, for example, can be used as a metal with biocidal effect. Silver is particularly suitable for this. At the same time, a precursor containing silicon, carbon, hydrogen and oxygen, such as, for example, the monomers HMDSO (hexamethyldisiloxane) or TEOS (tetraethoxysilane) is introduced into the vacuum working chamber and exposed to the plasma. Due to the activation of the precursor by the plasma and the simultaneous atomization of the metal, a mixed layer is deposited on the substrate. The constituents of the layer, which result from the plasma activation of the precursor, thereby form a matrix, in which the atomized metal particles are incorporated. Due to the tendency of the metal particles to agglomeration, they are incorporated into the matrix in the form of small concentrations, hereinafter also referred to as clusters. The clusters should thereby form a size of 3 nm to 40 nm.

The antimicrobial effect of a material of this type results from the fact that metal ions from the clusters diffuse through the matrix and having arrived at the surface of the material develop their biocidal effect.

The matrix thereby fulfils several functions. On the one hand, the matrix fixes the clusters in their position inside the material, thus counteracting the tendency of the metal particles to agglomerate, and thereby preventing the merging of several clusters. It therefore has a decisive influence on the size of the developing clusters. Since metal ions from clusters that are arranged, for example, near the surface of the layer material require a shorter time period until they diffuse at the surface than metal ions from clusters that are further removed from the surface the time period of the biocidal effect can be adjusted via the layer thickness of the material.

Furthermore, the diffusion paths and the diffusion coefficients of the metal ions inside the material are determined through the properties of the matrix. Thus, for example, the size of the clusters and the number of the clusters per volume unit have an effect on the time that a metal ion requires for the diffusion through a layer up to the surface. This time period is thereby longer, the larger the clusters and the higher the concentration of the clusters. However, this time period can also be influenced by additional oxygen being introduced into the vacuum working chamber and properties of the matrix thus being influenced. Thus, for example, an increase of the oxygen concentration in the vacuum working chamber has the effect that the diffusion period of metal ions through the matrix is prolonged.

Because the biocidal effect and the duration of effect is not only adjustable via the layer thickness, but is decisively determined by the properties of the matrix itself, in which the clusters are incorporated, the method according to the invention can also be used advantageously in the coating of woven fabric, without having to adjust anew a multilayered system regarding the biocidal action intensity and duration of effect with each type of woven fabric. Furthermore, other substrate materials such as, for example, nonwoven fabrics or plastic films can also be coated according to the invention.

If web-shaped substrates are coated with a method according to the invention and moved through the vacuum working chamber during the coating continuously at essentially constant speed, such that the concentration of the metal particles in the matrix is already adjusted to a desired value, then the layer thickness of the material to be deposited can also be controlled, for example, by the web speed.

With one embodiment the concentration of the clusters is embodied with a gradient from the surface of the layer material towards the substrate. Thus, for example, the biocidal effect can be intensified with an application with an increasing duration if the concentration of the clusters is embodied to increase towards the substrate and vice versa.

The atomizing of the metal with biocidal action can be carried out, for example, by means of a single magnetron with unipolar energy input. Alternatively, it is also possible to use a bipolar, double magnetron fed in a medium frequency manner for this. An advantageous design of the method with the double magnetron lies in that one magnetron is provided with a target of the metal with biocidal action and the other magnetron is provided with a target of titanium. Through suitable adjustments it can be achieved in this manner that the elements matrix layer and metal cluster can be influenced in an even more targeted manner. This can be realized in particular in that the distribution of the sputtering power between the two magnetrons is designed differently. For example, if the power of the magnetron with the metal with biocidal action is increased compared to the titanium target, the metal cluster content in the mixed layer increases. Furthermore, the additional atomization of titanium has a positive effect on the formation of the matrix, because a connecting layer is preferably formed on titanium targets through the reaction with precursor gases.

With a method according to the invention, the layer thickness and also the concentration of the metal particles in the matrix can be adjusted via the sputtering power and/or the quantity of the precursor introduced into the vacuum working chamber per time unit and/or the quantity of the oxygen introduced into the vacuum working chamber per time unit.

An advantageous embodiment of the method lies in observing the plasma emission of the process and to draw conclusions about the composition of the mixed layer forming based on the evaluation of several spectral lines. In particular it lends itself to undertaking an evaluation of the spectral line 656 nm for hydrogen, which provides information on the conversion of the precursor gas. This information can be combined with an evaluation of the spectral line 338 nm, which contains information about the silver content in the plasma.

Another possibility for monitoring or adjusting properties of a deposited layer results from a control of the deposition process depending on an evaluation of the reflection spectrum of a deposited layer material. With a change of the quantity of oxygen fed into a vacuum working chamber with otherwise constant deposition conditions, a discernible change of the reflection spectrum can be established.

### BRIEF DESCRIPTION OF THE DRAWINGS

The invention is described in more detail below based on a preferred exemplary embodiment. The figs. show:

FIG. 1 illustrates a diagrammatic representation of a coating device with which the method according to the invention can be carried out; and

FIG. 2 graphically represents the reflection spectrum of deposited layer materials with two different oxygen inflow quantities.

### DETAILED DESCRIPTION OF THE PRESENT INVENTION

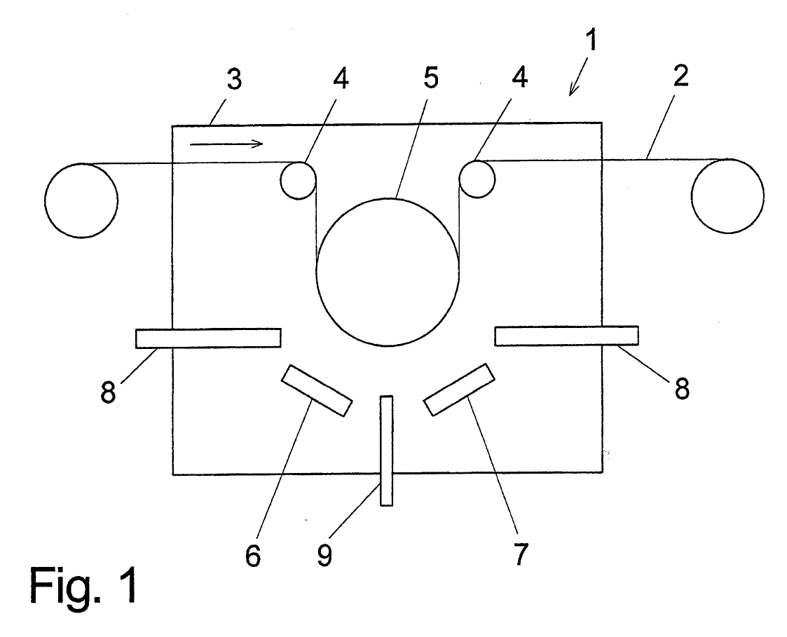

In FIG. 1, a coating device 1 is shown diagrammatically by which a material with biocidal action is to be deposited onto a substrate 2. Coating device 1 is embodied as a so-called roll-to-roll coater and comprises a vacuum working chamber 3 through which the substrate 2 is guided via deflection rollers 4 and a cooling roll 5 at a largely constant speed of 1 m/min. The web-shaped substrate 2 is a woven fabric 300 m long, 600 mm wide and 0.5 mm thick. The direction of movement of the web is indicated by an arrow.

Coating device 1 furthermore comprises a double magnetron with energy supply pulsed in a bipolar manner. A silver target 6 is assigned to one magnetron and a titanium target 7 is assigned to the other magnetron. During the sputtering, a plasma is formed between the targets 6 and 7, of which alternately one acts as an anode and the other as a cathode.

A gas mixture of the inert gas argon and the reactive gas oxygen is introduced via lines 8 into the vacuum working chamber 3. Argon as well as oxygen flows with approx. 150 seem into the vacuum working chamber 3. Likewise at the same time as the sputtering operation, the monomer HMDSO is introduced via a line 9 into the vacuum working chamber 3, which is activated by the plasma present there.

A total power of 12 kW is supplied to the double magnetron, and the magnetron which is assigned to the titanium target 7 is acted on with 60% of the total power.

Under the conditions given, the silver target 6 is very well atomized, whereas a connecting layer forms on the titanium target 7, which comprises on the one hand constituents of the monomer activated by the plasma and on the other hand reaction products of the titanium with oxygen.

The constituents of the monomer activated by the plasma as well as the particles sputtered by the titanium target of the connecting layer developing thereon form a matrix on the substrate 2, in which matrix particles sputtered from the silver target in the form of clusters are incorporated. The clusters are embodied with a size of approx. 10 nm and the material deposited on the substrate has a layer thickness of 100 nm, wherein the constituents silver and silicon are present in the layer material in a ratio of 1:1.

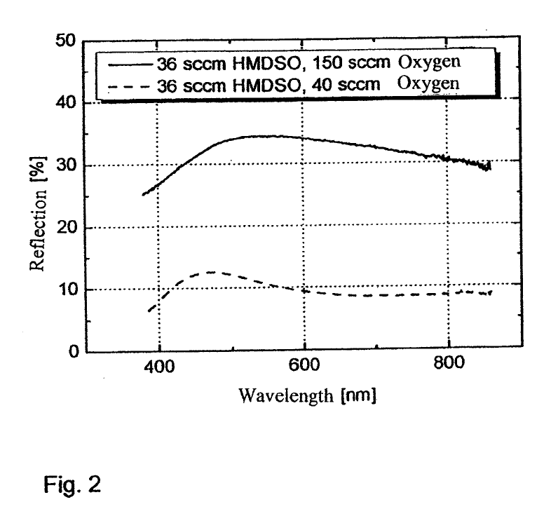

FIG. 2 illustrates graphically the dependence of reflection properties of a deposited layer material on the oxygen inflow quantity in a vacuum working chamber. The test set-up was hereby carried out with the same parameters as in the example description for FIG. 1. With a first sample coating the oxygen inflow quantity was set at 150 seem and with a second sample coating at 40 sccm. It is discernible from FIG. 2 that with the reflection spectra that were detected during the two sample coatings, it was possible to establish clearly perceptible differences in the reflection behavior of the layer material deposited. The detection of reflection properties of the deposited layer material therefore provides a good opportunity to detect values in the dependence of which properties of a deposited layer material can be verified or set. The effects the change of the oxygen flow has on properties of the layer material have already been described above.

1-21. (canceled)

21. A method for producing an antimicrobial material, which is deposited on a substrate, comprising:
providing the substrate in a vacuum working chamber;
atomizing a biocidal metal inside the vacuum working chamber in the presence of an inert gas to form metal particles;
introducing a precursor comprising silicon, carbon, hydrogen and oxygen into the vacuum working chamber, whereby that the metal particles and the precursor are exposed to a plasma action; and
depositing a material onto the substrate from a matrix formed through a plasma activation of the precursor, in which matrix clusters of the metal particles are incorporated.

22. The method in accordance with claim 21, wherein the biocidal metal is atomized by a sputtering device, and the precursor is simultaneously introduced as the biocidal metal is atomized by the sputtering device.

23. The method in accordance with claim 21, wherein the biocidal metal is silver.

24. The method in accordance with claim 21, wherein the biocidal metal is copper.

25. The method in accordance with claim 21, wherein the precursor is hexamethyldisilane.

26. The method in accordance with claim 21, wherein the precursor is tetraethoxysilane.

27. The method in accordance with claim 21, further comprising introducing oxygen into the vacuum working chamber.

28. The method in accordance with claim 27, further comprising adjusting a concentration of the metal particles in the matrix by at least one of a sputtering power; a quantity of the precursor introduced into the vacuum working chamber per time unit; and a quantity of oxygen introduced into the vacuum working chamber per time unit.

29. The method in accordance with claim 21, wherein a concentration of the metal particles in the matrix is embodied with a gradient towards the substrate such that a concentration of metal particles increases or decreases in the direction to the substrate.

30. The method in accordance with claim 27, further comprising adjusting a layer thickness of the material by at least one of a sputtering power, a quantity of precursor introduced into the vacuum working chamber per time unit, and a quantity of oxygen introduced into the vacuum working chamber per time unit.

31. The method in accordance with claim 21, wherein the substrate comprises a woven fabric or a nonwoven fabric.

32. The method in accordance with claim 21, wherein the substrate comprises a plastic film.

33. The method in accordance with claim 21, wherein the substrate comprises a web-shaped substrate that is continuously moved at an essentially constant speed through the vacuum working chamber during the depositing.

34. The method in accordance with claim 33, further comprising adjusting a layer thickness by adjusting a speed of the moving web within a predetermined concentration of the metal particles in the matrix.

35. The method in accordance with claim 21, wherein the sputtering device comprises a single magnetron with energy supply pulsed in a unipolar manner.

36. The method in accordance with claim 21, wherein the sputtering device comprises a double magnetron with medium-frequency energy supply pulsed in a bipolar manner.

37. The method in accordance with claim 36, wherein a target of the biocidal metal and a target of a further material are arranged inside the vacuum chamber.

38. The method in accordance with claim 21, wherein the further material is titanium.

39. The method in accordance with claim 21, wherein the matrix clusters are embodied with a size of 3 nm to 40 nm.

40. An antimicrobial material produced according to claim 1, the antimicrobial material comprising:
carbon, hydrogen, silicon and oxygen; and
clusters of particles of the biocidal metal with a size of 3 nm to 40 nm.

41. The antimicrobial material in accordance with claim 40, wherein the biocidal metal is one of silver, copper or zinc.
